(19) United States
(12) Patent Application Publication
(10) Pub. No.: US 2025/0194095 A1
(43) Pub. Date: Jun. 12, 2025

(54) FERROELECTRIC GATE STACK WITH TUNNEL DIELECTRIC INSERT FOR NAND APPLICATIONS

(71) Applicant: Samsung Electronics Co., Ltd., Suwon-si (KR)

(72) Inventors: Kijoon KIM, Suwon-si (KR); Dipjyoti DAS, Atlanta, GA (US); Kwangsoo KIM, Suwon-si (KR); Wanki KIM, Suwon-si (KR); Suhwan LIM, Suwon-si (KR); Daewon HA, Suwon-si (KR); Asif KHAN, Atlanta, GA (US); Chengyang ZHANG, Atlanta, GA (US); Chinsung PARK, Atlanta, GA (US); Hang CHEN, Atlanta, GA (US); Hyeonwoo PARK, Atlanta, GA (US); Mengkun TIAN, Atlanta, GA (US); Nashrah AFROZE, Atlanta, GA (US); PoKai HSU, Atlanta, GA (US); Prasanna Venkatesan RAVINDRAN, Atlanta, GA (US); Shimeng YU, Atlanta, GA (US); Suman DATTA, Atlanta, GA (US); Winston CHERN, Atlanta, GA (US); Zekai WANG, Atlanta, GA (US)

(73) Assignees: Samsung Electronics Co., Ltd., Suwon-si (KR); Georgia Tech Research Corporation, Atlanta, GA (US)

(21) Appl. No.: 18/815,936

(22) Filed: Aug. 27, 2024

Related U.S. Application Data
(60) Provisional application No. 63/606,684, filed on Dec. 6, 2023.

(51) Int. Cl. H10B 51/30; G11C 11/22; H10B 51/20

(52) U.S. Cl. CPC H10B 51/30; G11C 11/223; G11C 11/2275; H10B 51/20

(57) ABSTRACT

A ferroelectric gate stack may include a semiconductor layer, a conductor layer facing the semiconductor layer, a plurality of ferroelectric layers spaced apart from each other between the semiconductor layer and the conductor layer, a tunnel dielectric layer between a first ferroelectric layer and a second ferroelectric layer among the plurality of ferroelectric layers, and an interface layer between the semiconductor layer and the first ferroelectric layer.

### CROSS-REFERENCE TO RELATED APPLICATION(S)

This application claims the benefit of U.S. Provisional Application No. 63/606,684, filed on Dec. 6, 2023, the entire disclosure of which is incorporated herein by reference.

### BACKGROUND

### Field

The present disclosure relates to a ferroelectric gate stack with a tunnel dielectric insert, a memory device including the same, a memory system including the memory device, and/or a method of manufacturing the same.

### Description of Related Art

Three-dimensional (3-D) NAND flash based on the charge trap nitride (CTN) gate stack is the workhorse technology for data storage, spanning from enterprise to mobile and edge computing, and emerging AI applications, primarily due their high density. The aggressive Z-pitch scaling that enables massive bit cell density in 3D-NAND, however, comes at the expense of increased write voltage due to reduced gate control. This, in turn, leads to issues such as reduced speed, increased cell size, and higher power consumption at the system level due to the high-voltage requirement of peripheral circuits, like charge pumps. These factors adversely affect the further scaling potential of 3D NAND flash technology.

To that end, the ferroelectric gate stack has recently gained attention as a possible replacement for the CTN layer in the 3D NAND architecture due to the low write voltage of ferroelectric field effect transistors (FEFETs). However, designing a ferroelectric (FE) gate stack for NAND applications therefore presents a multifaceted challenge.

One of the primary difficulties lies in the trade-off between achieving the theoretical maximum memory window (MW), which can be represented as 2E_{c}*t_{f} (where E_{c} represents the coercive field and t_{f} is the thickness of the FE layer), and maintaining an appropriate thickness for the FE layer. Increasing the thickness of the FE layer is not a straightforward solution for enhanced MW due to the thickness limit of 3D-NAND. Increasing the thickness of the FE layer also can lead to the loss of ferroelectricity of the FE layer. Further, the practical MW is often lower than the theoretical limit. On the Si platform, the practical MW is limited to ≤3 V, irrespective of write voltage and FE thickness due to charge injection and trapping effects, necessitating careful optimization.

Balancing these factors and addressing their interplay is a complex task, making the design of FE gate stacks for 3D-NAND a highly intricate engineering problem.

### SUMMARY

Some example embodiments of the present disclosure relates to a ferroelectric gate stack with an enhanced memory window (MW).

Some example embodiments relate to a memory device and a memory system including a ferroelectric gate stack with an enhanced MW.

According to an example embodiment, a ferroelectric gate stack may include a semiconductor layer; a conductor layer facing the semiconductor layer; a plurality of ferroelectric layers spaced apart from each other between the semiconductor layer and the conductor layer, the plurality of ferroelectric layers including a first ferroelectric layer and a second ferroelectric layer; a tunnel dielectric layer between the first ferroelectric layer and the second ferroelectric layer; and an interface layer between the semiconductor layer and the first ferroelectric layer.

According to an example embodiment, a memory device may include a channel; a source connected to a first end of the channel; a drain connected to a second end of the channel; a conductor layer facing the channel; a plurality of ferroelectric layers spaced apart from each other between the channel and the conductor layer, the plurality of ferroelectric layers including a first ferroelectric layer and a second ferroelectric layer; a tunnel dielectric layer between the first ferroelectric layer and the second ferroelectric layer; and an interface layer between the channel and the first ferroelectric layer.

According to an example embodiment, a ferroelectric gate stack may include a semiconductor layer; a conductor layer facing the semiconductor layer; a ferroelectric (FE) stack between the semiconductor layer and the conductor layer, the FE stack including a plurality of ferroelectric material regions separated from each other by one or more tunnel dielectric regions in contact with the plurality of ferroelectric material regions; and an interface layer between the semiconductor layer and the FE stack. The plurality of ferroelectric material regions may include a ferroelectric material. The one or more tunnel dielectric regions may include a dielectric material configured to increase a memory window of the ferroelectric gate stack. The ferroelectric material may be different than the dielectric material and different than a material of the interface layer. Opposite surfaces of the interface layer may be in contact with the semiconductor layer and the FE stack.

Accordingly to an example embodiment, a method of manufacturing a ferroelectric gate stack may include forming a semiconductor layer; forming an interface layer on the semiconductor layer; forming a ferroelectric (FE) stack on the interface layer; and forming a conductor layer on the FE stack. The FE stack may include a plurality of ferroelectric layers separated from each other by a tunnel dielectric layer in contact with the plurality of ferroelectric layers. The plurality of ferroelectric layers may include a ferroelectric material. The ferroelectric material may be different than a dielectric material in the tunnel dielectric layer and different than a material of the interface layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a cross-sectional diagram of a conventional ferroelectric gate stack;

FIGS. 2A to 2B are cross-sectional diagrams of ferroelectric gate stacks according to some example embodiments of the present disclosure;

FIGS. 2C, 2D, and 2E respectively are a plan view, a perspective view, and a cross-sectional view of a memory cell stack including a ferroelectric gate stack according to an example embodiment of the present disclosure;

FIGS. 2F, 2G, and 2H respectively are a plan view, a perspective view, and a cross-sectional view of a memory cell stack including a ferroelectric gate stack according to an example embodiment of the present disclosure;

FIGS. 3A and 3B are graphs for explaining the impact of a tunnel dielectric layer on threshold voltage and memory window in a ferroelectric gate stack according to some example embodiments as a function of write voltages;

FIG. 3C is a TEM (transmission electron microscope) image of a ferroelectric gate stack according to an example embodiment;

FIGS. 4A to 4C are graphs for explaining the impact of tunnel dielectric layer thicknesses on memory window in ferroelectric gate stacks according to some example embodiments as a function of write voltages;

FIGS. 5A to 5D are cross-sectional views of memory devices according to some example embodiments;

FIG. 5E is a block diagram of a memory system according to an example embodiment;

FIG. 6 is a flow chart with cross-sectional diagrams for explaining to a method of manufacturing a ferroelectric gate stack and a memory device according to an example embodiment; and

FIG. 7 is a flow chart with cross-sectional diagrams for explaining a method of manufacturing a ferroelectric gate stack and a memory device according to an example embodiment.

### DETAILED DESCRIPTION

Hereinafter, embodiments of the present disclosure will be described as follows with reference to the accompanying drawings. Hereinafter, terms such as “upper portion,” “middle portion,” and “lower portion” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC. As used herein, the singular forms “a,” “an” and “the” are intended to include the plural forms as well, unless the context clearly indicates otherwise.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

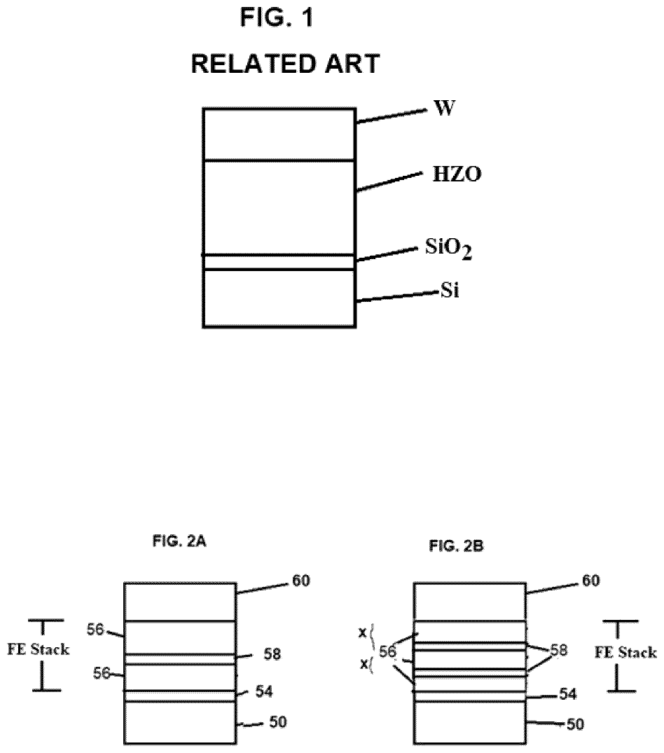

FIG. 1 is a cross-sectional diagram of a conventional ferroelectric gate stack.

Referring to FIG. 1, a conventional ferroelectric gate stack may include a structure in which a silicon (Si) layer, a silicon oxide (SiO₂) layer, a hafnium zirconium oxide (HZO) layer, and a tungsten (W) layer are sequentially stacked.

The conventional ferroelectric gate stack is not yet a suitable drop-in replacement for the charge trap nitride (CTN) layer in the 3D NAND architecture because of two main constraints. First, the memory window (MW) of the conventional ferroelectric gate stack is not large enough to support multi-bit operation. To support multi-bit operation, the MW should be ≥3 V for 2 bit multi-level cell (MLC) and ≥6.5 V for 3-bit cell triple-level cell (TLC) with the write voltage limited to 15 V, but the practical MW of the conventional ferroelectric gate stack is limited to ≤3 V. Second, to accommodate the core-shell structure within the hole diameter of 100-120 nm of the vertical NAND string, the thickness of the gate stack should be limited to ˜20 nm. As a result, increasing the thickness of the HZO layer is not a straightforward solution for increasing the MW. Increasing the thickness of the HZO layer too much also can lead to the loss of ferroelectricity of the HZO layer.

However, the inventors of the present application have discovered that inserting at least one tunnel dielectric layer (TDL) in the HZO layer of a ferroelectric gate stack, which divides the HZO layer into separate regions, overcomes limitations related to the conventional ferroelectric gate stack. Ferroelectric gate stacks according to example embodiments unexpectedly have an increased memory window (MW) compared to the conventional ferroelectric gate stack.

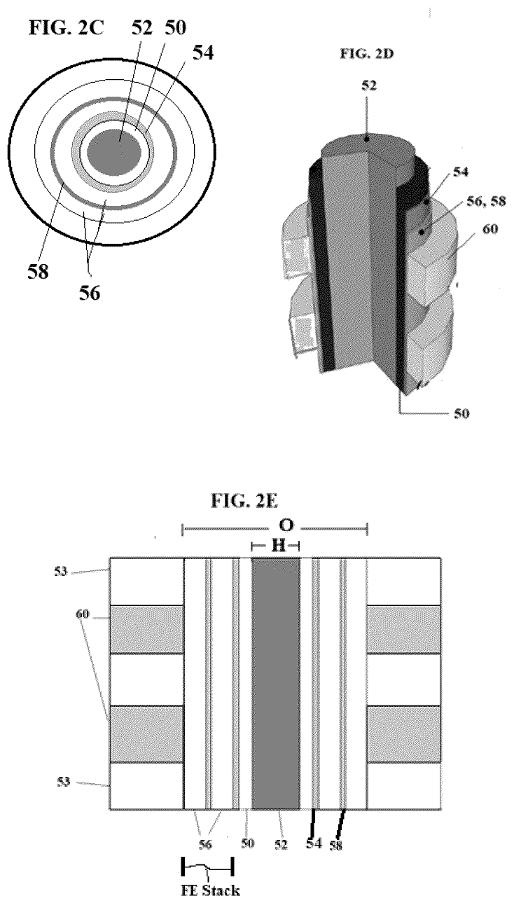

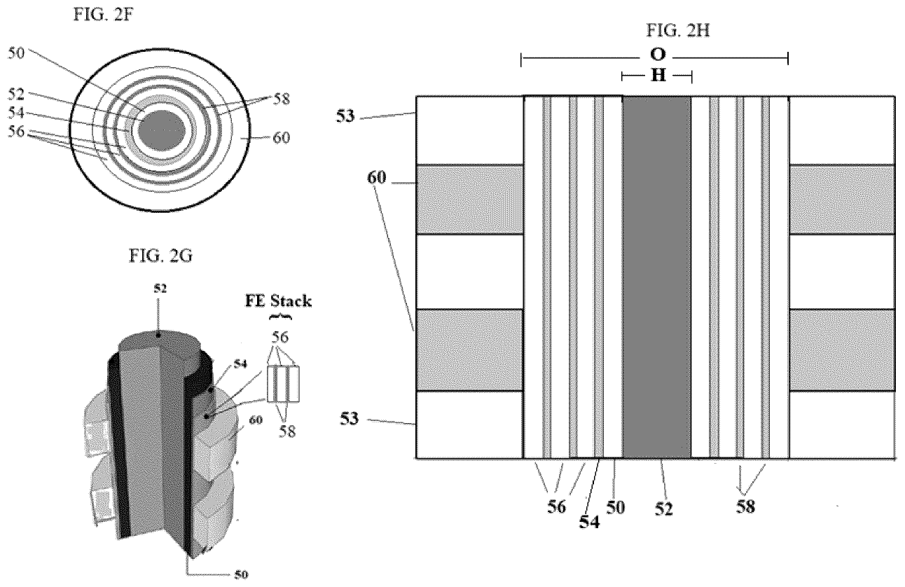

FIGS. 2A to 2B are cross-sectional diagrams of ferroelectric gate stacks according to some example embodiments of the present disclosure.

Referring to FIG. 2A, in an example embodiment, a ferroelectric gate stack may include a semiconductor layer 50, a conductor layer 60 facing the semiconductor layer 50, a ferroelectric (FE) stack between the semiconductor layer 50 and the conductor layer 60, and an interface layer 54 between the semiconductor layer 50 and the FE stack. The conductor layer 60, FE stack, and semiconductor layer 50 may extend parallel to each other, in which case the conductor layer 60 may not surround the semiconductor layer 50.

The semiconductor layer 50 may include a group IV semiconductor material, a group III-V semiconductor material, an oxide semiconductor material, or a transition metal dichalcogenide (TMD). More specifically, the semiconductor layer 50 may include silicon (Si) (e.g., monocrystalline Si or polycrystalline Si), germanium (Ge), silicon germanium (SiGe), gallium arsenide (GaAs), gallium nitride (GaN), indium gallium zinc oxide (InGaZnO), graphene, or molybdenum sulfide (MoS₂), but is not limited thereto. The semiconductor layer 50 may be undoped or the semiconductor layer 50 may be doped with a p-type or n-type impurity. The semiconductor layer 50 may correspond to a region of a bulk substrate, a separate layer on the substrate, or a region of the separate layer on the substrate.

The conductor layer 60 may include an electrically-conductive material such as a metal, a metal alloy, a metal nitride, or a combination thereof. The conductor layer may include tungsten (W), aluminum (Al), molybdenum (Mo), titanium (Ti), tantalum (Ta), TiAl, TiAlN, WN, AlN, TiN, or TaN. or a combination thereof, but is not limited thereto. In some embodiments, the conductor layer 60 may include a multilayer structure having a metal nitride layer and a meta layer or metal alloy layer on the metal nitride layer, where the metal nitride layer may be disposed between the FE stack and the metal or metal alloy layer. For example, the conductor layer 60 may include TiN/W multilayer structure on the FE stack.

The FE stack may include a plurality of ferroelectric material regions separated from each other by one or more tunnel dielectric regions in contact with the plurality of ferroelectric material regions. Each tunnel dielectric region may be sandwiched between a pair of ferroelectric material regions. The ferroelectric material regions may include a ferroelectric material such as HZO, a Hf-based oxide, or a Zr-based oxide, and the ferroelectric material may have a fluorite crystal structure, but these are just example materials and other fluorite-structured ferroelectric materials may be suitable for the ferroelectric material regions. The tunnel dielectric regions may include a dielectric material configured to increase a memory window of the ferroelectric gate stack. The dielectric material of the tunnel dielectric regions may be different than the ferroelectric material. The dielectric material of the tunnel dielectric region(s) may include aluminum oxide (Al₂O₃), but other dielectric materials may be used, such as silicon oxide (SiO₂). The ferroelectric material regions each may correspond to a ferroelectric layer including the ferroelectric material. The tunnel dielectric region(s) each may correspond to a layer including the dielectric material.

In FIG. 2A, the FE stack may include a plurality of ferroelectric layers 56 spaced apart from each other between the semiconductor layer 50 and the conductor layer 60, and a tunnel dielectric layer 58 between the plurality of ferroelectric layers 56. The lower and upper ferroelectric layers 56 in the FE stack respectively may be referred to as a first ferroelectric layer 56 and a second ferroelectric layer 56, and the tunnel dielectric layer 58 may be between the first and second ferroelectric layers 56. The interface layer 54 may be between the semiconductor layer 50 and the first ferroelectric layer 56. The tunnel dielectric layer 58 also may be referred to as a tunnel dielectric insert.

Adjacent layers in the ferroelectric gate stack of FIG. 2A may directly contact each other. The interface layer 54 may be directly on the semiconductor layer 50. The first ferroelectric layer 56 may be directly on the interface layer 54. Thus, opposite surfaces of the interface layer may directly contact the first ferroelectric layer 56 and the semiconductor layer 50, respectively. The tunnel dielectric layer 58 may be directly on the first ferroelectric layer 56. Thus, opposite surfaces of the tunnel dielectric layer 58 may directly contact the first ferroelectric layer 56 (lower ferroelectric layer) and the second ferroelectric layer 56 (upper ferroelectric layer), respectively. The second ferroelectric layer 56 may be directly on the tunnel dielectric layer 58. The conductor layer 60 may be directly on the second ferroelectric layer 56. Thus, opposite surfaces of the second ferroelectric layer 56 may directly contact the tunnel dielectric layer 58 and the conductor layer 60, respectively.

The ferroelectric material in the plurality of ferroelectric layer 56 may be a different material than the material of the interface layer 54 and the material of the tunnel dielectric layer 58. The interface layer 54 may include an oxide of a material in the semiconductor layer 50. For example, the interface layer 54 may include silicon oxide when the semiconductor layer includes silicon. In one example, the interface layer 54 may include silicon oxide, the plurality of ferroelectric layers 56 may include HZO, and the tunnel dielectric layer 58 may include aluminum oxide. When the plurality of ferroelectric layer 56 include HZO, the HZO may be in crystalline form (e.g., fluorite-structured) and may include a solid solution of hafnium zirconium oxide. However, example embodiments are not limited thereto.

Referring to FIG. 2B, in an example embodiment, a ferroelectric gate stack may be the similar to the ferroelectric gate stack described in FIG. 2A, except the FE stack may have a nanolaminate structure where at least three ferroelectric layers 56 may be alternately stacked with at least two tunnel dielectric layers 58. When the FE stack has the nanolaminate structure, unit layers X may be sequentially stacked on the first ferroelectric layer 56 (or ferroelectric layer 56 closest to the semiconductor layer 50). Each unit layer X may include a tunnel dielectric layer 56 facing towards the semiconductor layer 50 and a ferroelectric layer 56 facing towards the conductor layer 60. The nanolaminate structure may include one tunnel dielectric layer 58 sandwiched between each pair of adjacent ferroelectric layers 56.

As shown in FIG. 2B, the FE stack may include a first ferroelectric layer 56 (lower ferroelectric layer 56) on the interface layer 54, a first tunnel dielectric layer 58 (lower tunnel dielectric layer 58) on the first ferroelectric layer 56, a second ferroelectric layer 56 (middle ferroelectric layer 56) on the first tunnel dielectric layer 58, a second tunnel dielectric layer 58 (upper tunnel dielectric layer 58) on the second ferroelectric layer 56, and a third ferroelectric layer 56 (upper ferroelectric layer 58) on the second tunnel dielectric layer 58. Each one of the tunnel dielectric layers 58 may have opposite surfaces directly contacting adjacent ferroelectric layers 56 in the FE stack. The conductor layer 60 may directly contact a surface of the third ferroelectric layer 56 that is farthest away from the semiconductor layer 50. When the FE stack includes more than three ferroelectric layers 56, the conductor layer 60 may directly contact one of the ferroelectric layers 56 that is farthest away from the semiconductor layer 50 among the ferroelectric layers 56.

FIGS. 2C, 2D, and 2E respectively are a plan view, a perspective view, and a cross-sectional view of a memory cell stack including a ferroelectric gate stack according to an example embodiment of the present disclosure.

Referring to FIG. 2C to 2E, in an example embodiment, a ferroelectric gate stack of a memory cell stack may be the similar to the ferroelectric gate stack described in FIG. 2A, except the semiconductor layer 50 and the conductor layer 60 respectively may extend in directions crossing each other. The memory cell stack in FIGS. 2C to 2E may include a plurality of conductor layers 60 and insulating interlayers 53 alternately stacked on top of each other. The conductor layers 60 and insulating interlayers 53 may define an opening O through a thickness direction of the memory cell stack. The semiconductor layer 50 may extend through the opening O. The conductor layers 60 and the insulating interlayers 53 may surround the semiconductor layer 50.

As shown in FIGS. 2C to 2E, an internal surface of the semiconductor layer 50 may surround an insulating filler layer 52. The insulating filler layer 52 may fill a hole H defined by an internal surface of the semiconductor layer 50 and may extend in the same direction as the semiconductor layer 50. The insulating filler layer 52 may include an insulating material such as silicon oxide, but the insulating material of the insulating filler layer 52 is not limited to silicon oxide. In some embodiments, the insulating filler layer 52 may be omitted and the semiconductor layer 50 may fill the area occupied by the insulating filler layer 52 in FIGS. 2C to 2E. For example, the semiconductor layer 50 may have a cylindrical shape instead of the annular shape shown in FIGS. 2C to 2E.

The interface layer 54 may surround an outer surface of the semiconductor layer 50 and may extend in the same direction as the semiconductor layer 50 through the opening O. A FE stack surround an outer surface of the interface layer 54 and may extend in the same direction as the semiconductor layer 50 through the opening O. The FE stack may include a tunnel dielectric layer 58 sandwiched between two ferroelectric layers 56. The tunnel dielectric layer 58 may extend in the same direction as the semiconductor layer 50 through the opening O. The ferroelectric layer 56 closest to the semiconductor layer 50 may be referred to as the first ferroelectric layer 56 and the ferroelectric layer 56 closest to the conductor layer 60 may be referred to as the second ferroelectric layer 56. Opposite surfaces of the tunnel dielectric layer 58 may directly contact the first ferroelectric layer 56 and the second ferroelectric layer 56, respectively. Opposite surfaces of the interface layer 54 may directly contact the first ferroelectric layer 56 and the semiconductor layer 50, respectively.

FIGS. 2F, 2G, and 2H respectively are a plan view, a perspective view, and a cross-sectional view of a memory cell stack including a ferroelectric gate stack according to an example embodiment of the present disclosure.

Referring to FIG. 2F to 2H, in an example embodiment, a ferroelectric gate stack may be similar to the ferroelectric gate stack described in FIGS. 2C to 2E, except the FE stack may have a nanolaminate structure including three ferroelectric layers 56 alternately stacked with two tunnel dielectric layers 58. Each tunnel dielectric layer 58 may be sandwiched between a pair of adjacent ferroelectric layers 56 in the FE stack. Each one of the tunnel dielectric layers 58 may have opposite surfaces directly contacting adjacent ferroelectric layers 56 in the FE stack. The conductor layer 60 may directly contact a surface of the ferroelectric layer 56 in the FE stack that is farthest from the semiconductor layer 50. The interface layer 54 may directly contact a surface of the ferroelectric layer 56 in the FE stack that is farthest from the conductor layer 60. Opposite surfaces of the interface layer 54 may directly contact a surface of the semiconductor layer 50 and a surface of the ferroelectric layer 56 in the FE stack that is farthest from the conductor layer 60, respectively.

In the FE stack illustrated in FIGS. 2F to 2H, in a direction from the semiconductor layer 50 to the conductor layer 60, the three ferroelectric layers 56 respectively may referred to as a first ferroelectric layer 56, a second ferroelectric layer 56, and a third ferroelectric layer 56. The tunnel dielectric layer 58 closest to the semiconductor layer 50 may be referred to as a first tunnel dielectric layer 58. The tunnel dielectric layer 58 closest to the conductor layer 60 may be referred to as a second tunnel dielectric layer 58.

Although FIGS. 2F to 2H illustrate an example where the FE stack includes three ferroelectric layers 56 alternately stacked with two tunnel dielectric layers 58 in a direction from the semiconductor layer 50 to the conductor layer 60, example embodiments are not limited thereto. In some embodiments, the FE stack may include more than three ferroelectric layers 56 alternately stacked with more than two tunnel dielectric layers 58 in a direction from the semiconductor layer 50 to the conductor layer 60, where each tunnel dielectric layer 58 may be sandwiched between a pair of adjacent ferroelectric layers 56.

Referring to FIGS. 2A to 2H, the semiconductor layer 50 and the conductor layer 60 may be separated from each other by a distance of less than or equal to 20 nm, in which case the plurality of ferroelectric layers 56, the tunnel dielectric layer(s) 58, and the interface layer 54 may define a stacked structure having a thickness of less than or equal to 20 nm. The thickness of less than or equal to 20 nm may be in a direction corresponding to a minimum distance between the semiconductor layer 50 from the conductor layer 60. A thickness of the interface layer 54 may be less than thicknesses of the ferroelectric layers 56. A thickness of the tunnel dielectric layer(s) 58 may be less than thicknesses of the ferroelectric layers 56. The thickness of the interface layer 54 may be 2 nm or less, or 1 nm or less. A thickness of the tunnel dielectric layer(s) 58 may be at least 0.5 nm and 4.0 nm or less, 3.0 nm or less, 2.0 nm or less, or 1.0 nm or less. The plurality of ferroelectric layers each may have a thickness in a range of 6 nm to 12 nm, 7 nm to 11 nm, or 8 nm to 10 nm. However, example embodiments are not limited thereto.

The semiconductor layer 50 may provide a channel and a distance between the channel and the conductor layer 60 may be 20 nm or less. The distance between the channel and the conductor layer 60 corresponds to a thickness of a stacked structure consisting of the plurality of ferroelectric layers 56, the tunnel dielectric layer 58, and the interface layer 54.

### Examples

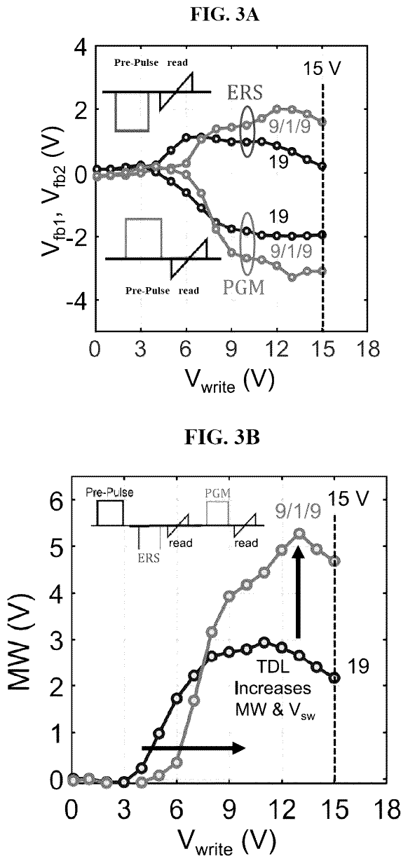

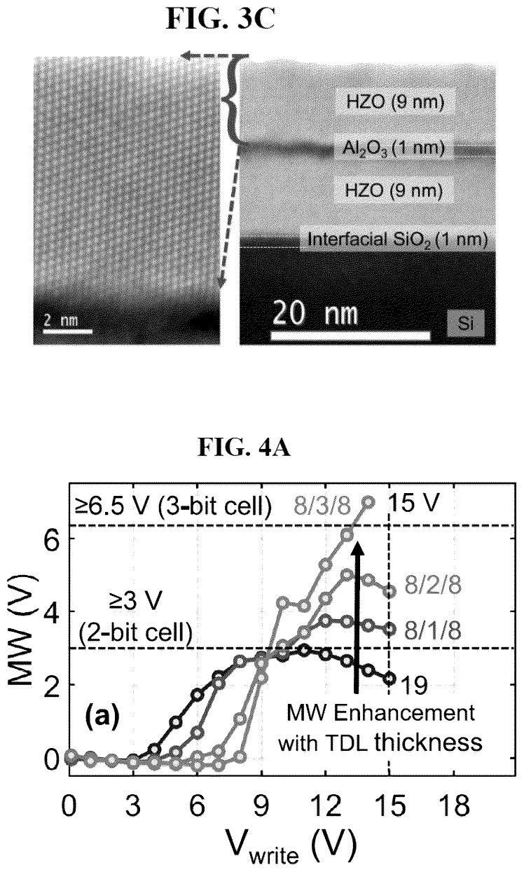

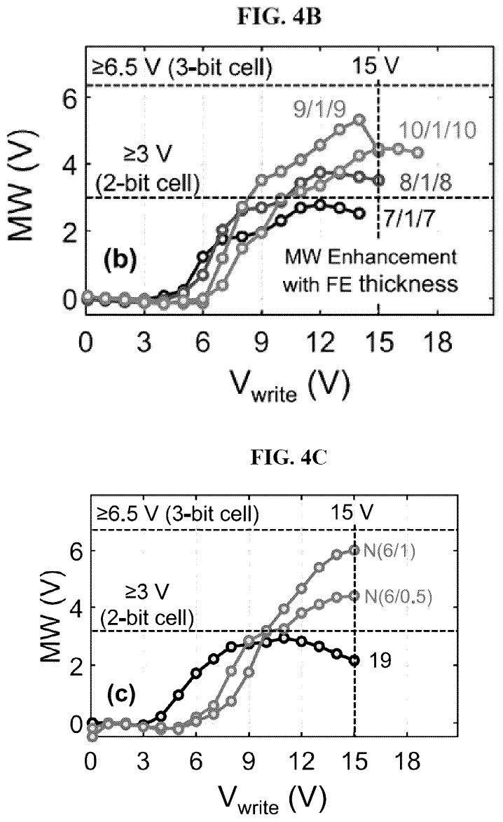

Referring to FIGS. 3A to 3C and 4A to 4C, embodiments are described in more detail with reference to Comparative Example 1 and Examples 1 to 8. However, these examples are non-limiting, and inventive concepts are not limited to Examples 1 to 8.

The physical operation of the ferroelectric field effect transistors (FEFETs) of Comparative Example 1 and Examples 1 to 8 is as follows:
1. A program or erase voltage is applied switching the polarization of the FE layer,
2. The threshold voltage (Vth) of the FEFET shifts according to the polarization state of the FE layer,
3. A positive program pulse shift the Vth to VtLow whereas a negative Erase pulse shift the Vth to VtHigh,
4. The difference between the VtHigh and VtLow is termed as MW, and
5. The theoretical maximum MW of FEFET (2E_{c}*t_{f}) is limited by the thickness of the FE layer, and on the Si platform practical MW is limited to ≤3 V irrespective of write voltage and FE thickness due to charge injection and trapping effects.

Without wishing to be bound by theory, the inventors unexpectedly have discovered engineering the FE gate stack by the insertion of a tunnel dielectric layer (TDL) can leverage trap dynamics to enhance the MW. The electrons (holes) trapped at the FE-TDL interfaces to screen the FE bound charges form a local, artificial dipole across the TDL. The direction of the dipole is such that the resulting built-in electric field in the TDL unexpectedly enhances the Vt shift caused by FE polarization, instead of diminishing it, thereby increasing the effective MW of the FEFET.

In FIGS. 3A to 3C and 4A to 4C, FEFETs with different ferroelectric gate stacks were prepared. Comparative Example 1 (data labeled “19) was prepared with a conventional ferroelectric gate stack having a 1 nm SiO₂ layer and 19 nm HZO layer sequentially stacked between a Si layer and a W layer, and no tunnel dielectric layer between the 1 nm SiO₂ layer and 19 nm HZO layer.

Example 1 (data labeled “9/1/9”) was prepared with a ferroelectric gate stack having a 1 nm SiO₂ layer, a 9 nm HZO layer, a 1 nm Al₂O₃ layer, and a 9 nm HZO layer sequentially stacked between a Si layer and a W layer. Example 2 (data labeled “8/1/8”) was prepared with a ferroelectric gate stack having a 1 nm SiO₂ layer, a 8 nm HZO layer, a 1 nm Al₂O₃ layer, and a 8 nm HZO layer sequentially stacked between a Si layer and a W layer. Example 3 (data labeled “8/2/8”) was prepared with a ferroelectric gate stack having a having a 1 nm SiO₂ layer, a 8 nm HZO layer, a 2 nm Al₂O₃ layer, and a 8 nm HZO layer sequentially stacked between a Si layer and a W layer.

Example 4 (data labeled “8/3/8”) was prepared with a ferroelectric gate stack having a 1 nm SiO₂ layer, a 8 nm HZO layer, a 3 nm Al₂O₃ layer, and a 8 nm HZO layer sequentially stacked between a Si layer and a W layer. Example 5 (data labeled “7/1/7”) was prepared with a ferroelectric gate stack having a 1 nm SiO₂ layer, a 7 nm HZO layer, a 1 nm Al₂O₃ layer, and a 7 nm HZO layer sequentially stacked between a Si layer and a W layer. Example 6 (data labeled “10/1/10”) was prepared with a ferroelectric gate stack having a 1 nm SiO₂ layer, a 10 nm HZO layer, a 1 nm Al₂O₃ layer, and a 10 nm HZO layer sequentially stacked between a Si layer and a W layer.

Example 7 (data labeled “N(6/0.5)”) was prepared with a ferroelectric gate stack having a 1 nm SiO₂ layer, a 6 nm HZO layer, a 0.5 nm Al₂O₃ layer, a 6 nm HZO layer, a 0.5 nm Al₂O₃ layer, and a 6 nm HZO layer sequentially stacked between a Si layer and a W layer. Example 8 (data labeled “N(6/1)”) was prepared with a ferroelectric gate stack having a 1 nm SiO₂ layer, a 6 nm HZO layer, a 1 nm Al₂O₃ layer, a 6 nm HZO layer, a 1 nm Al₂O₃ layer, and a 6 nm HZO layer sequentially stacked between a Si layer and a W layer.

FIGS. 3A and 3B are graphs for explaining the impact of a tunnel dielectric layer (TDL) on threshold voltage and memory window in a ferroelectric gate stack according to some example embodiments. FIG. 3C is a TEM (transmission electron microscope) image of a ferroelectric gate stack according to an example embodiment. FIG. 3C is a TEM image of a ferroelectric gate stack prepared according to Example 1 (data labeled “9/1/9”) except without the W layer on top of the upper HZO layer.

In FIG. 3A, erase (ERS) operations and program (PGM) operations were performed on the FEFETs for Comparative Example 1 (data labeled “19”) and Example 1 (data labeled “9/1/9”) while the write voltage Vwrite was incrementally increased from 0 V to 15V.

As shown in FIG. 3A, the erase (ERS) operation included a rectangular erase-voltage pulse (Pre-Pulse) followed by a delay time and a ramped read voltage (read). The program (PGM) operation included a rectangular program-voltage pulse (Pre-Pulse) followed by a delay time and a ramped read voltage (read). The write voltage Vwrite level for the erase-voltage pulse was negative and the write voltage Vwrite level for the program-voltage pulse was positive. The write voltage Vwrite (program-voltage pulse or erase-voltage pulse) and ramped read voltage Vread were applied to the W layers for the FEFETs for Comparative Example 1 (data labeled “19”) and Example 1 (data labeled “9/1/9”).

The X-axis in FIG. 3A shows the write voltage Vwrite was incrementally varied from 0 to 15 V. On the Y-axis in FIG. 3A, Vfb1 and Vfb2 corresponds to the flatband voltages for Comparative Example 1 (data labeled “19”) and Example 1 (data labeled “9/1/9”) at different write voltage Vwrite levels for the erase (ERS) operations and program (PGM) operations. As shown in FIG. 3A, as the write voltage Vwrite was incrementally increased from 0 V to 15 V, the difference between Vfb1 and Vfb2 became greater in Example 1 (data labeled “9/1/9”) than Comparative Example 1 (data labeled “19”).

Referring to FIG. 3B, the insertion of the tunnel dielectric layer (1 nm Al₂O₃ layer) in Example 1 (data labeled “9/1/9”) increased the memory window (MW) and switch voltage (Vsw) compared to Comparative Example 1 (data labeled “19”). As the write voltage Vwrite was incrementally increased from 0 V to 15 V, the MW became higher in Example 1 (data labeled “9/1/9”). When the write voltage Vwrite was greater than 7 V and less than or equal to 15 V, the MW in Example 1 (data labeled “9/1/9”) was greater than the MW in Comparative Example 1 (data labeled “19”).

To support multi-bit operation, the MW should be ≥3 V for 2 bit cell (MLC) and >6.5 V for 3-bit cell (TLC) with the write voltage limited to 15 V. Example 1 (data labeled “9/1/9”) achieved the MW of ≥3 V, which is sufficient to support operation of the 2 bit cell (MLC), but Comparative Example 1 (data labeled “19”) did not achieve the MW sufficient to support operation of the 2 bit cell (MLC). The MW for Comparative Example 1 (data labeled “19”) remained under 3 V as the write voltage Vwrite was incrementally increased from 0 to 15 V.

FIGS. 4A to 4C are graphs for explaining the impact of tunnel dielectric layer thicknesses on memory window in ferroelectric gate stacks according to some example embodiments as a function of write voltage Vwrite.

Referring to FIG. 4A, Example 2 (data labeled “8/1/8”), Example 3 (data labeled “8/2/8”), and Example 4 (data labeled “8/3/8”) all achieved MWs sufficient to support multi-bit operation. Example 2 (data labeled “8/1/8”), Example 3 (data labeled “8/2/8”), and Example 4 (data labeled “8/3/8”) achieved MWs of greater than or equal to 3 V, which is sufficient to support 2-bit (MLC) operation. Example 4 (data labeled “8/3/8”) also achieved a MW of greater than or equal to 6.5 V, which is sufficient to support 3-bit cell (TLC) operation.

As shown in FIG. 4A, as the thickness of the tunnel dielectric layer was increased from 1 nm to 3 nm in Example 1 (data labeled “9/1/9”), Example 2 (data labeled “8/1/8”), Example 3 (data labeled “8/2/8”), and Example 4 (data labeled “8/3/8”), the MW also was increased.

Referring to FIG. 4B, Example 1 (data labeled “9/1/9”), Example 2 (data labeled “8/1/8”), and Example 6 (data labeled “10/1/10) all achieved MWs sufficient to support multi-bit operation. Example 1 (data labeled “9/1/9”), Example 2 (data labeled “8/1/8”), and Example 6 (data labeled “10/1/10) achieved MWs of greater than or equal to 3 V, which is sufficient to support 2-bit (MLC) operation.

Referring to FIG. 4C, Example 7 (data labeled “N(6/0.5)”) and Example 8 (data labeled “N(6/1)”) all achieved MWs sufficient to support multi-bit operation. Example 7 (data labeled “N(6/0.5)”) and Example 8 (data labeled “N(6/1)”) achieved MWs of greater than or equal to 3 V, which is sufficient to support 2-bit (MLC) operation.

FIGS. 3A, 3B, and 4A to 4C experimentally demonstrate a novel dipole engineering scheme to achieve significantly high MW (≥3.0 V and/or ≥6.5 V) in FE stack within the NAND thickness limit (≤20 nm). This scheme involves engineering the FE gate stack by the insertion of a TDL and leverage trap dynamics to enhance the MW. The presence of TDL increases the Vfb shifts, MW and write voltage as evident from FIGS. 3A and 3B. Further, a clear dependence of switching voltage onset and MW can be observed with the TDL or the FE layer thickness in the gate stack. MW increases significantly with increasing the Al₂O₃ and FE thickness with a concurrent increase in write voltage, as shown in FIGS. 4A to 4C.

Initially, the polarization at FE-TDL interface is assumed to be screened by the electrons (holes) at acceptor (donor)-like traps. The polarization will switch in the opposite direction, if a voltage close to −(+)Vc is applied during program (erase) operation. This leads to a mismatch with the existing screening charge, resulting in a very high electric field across the TDL layer. As a result, the trapped charges get emitted and tunnel through the triangular barrier in TDL. The electrons (holes) tunneling across the TDL barrier can be captured by the empty acceptor (donor)-like traps at the opposite interface of TDL, due to the presence of polarization charge of the opposite polarity. Consequently, the tunneling, and electron (hole) capture mechanism allows for the switching of the polarization, followed by a shift in position of the screening charges at the TDL interfaces. However, under the flat band condition, the screening charge still maintains the same polarity as that of the previous polarization state. This is due to a delay between the polarization switching and the change of the screening charge. The remaining screening charges form dipoles and generates a finite electric field in the TDL layer. Thus, a voltage drop occur in the TDL layer enabling an increase of the MW (ΔV_{MW}/2) in each threshold voltage in addition to the original MW (2(V_{c}+V_{c})) of the standard FEFETs.

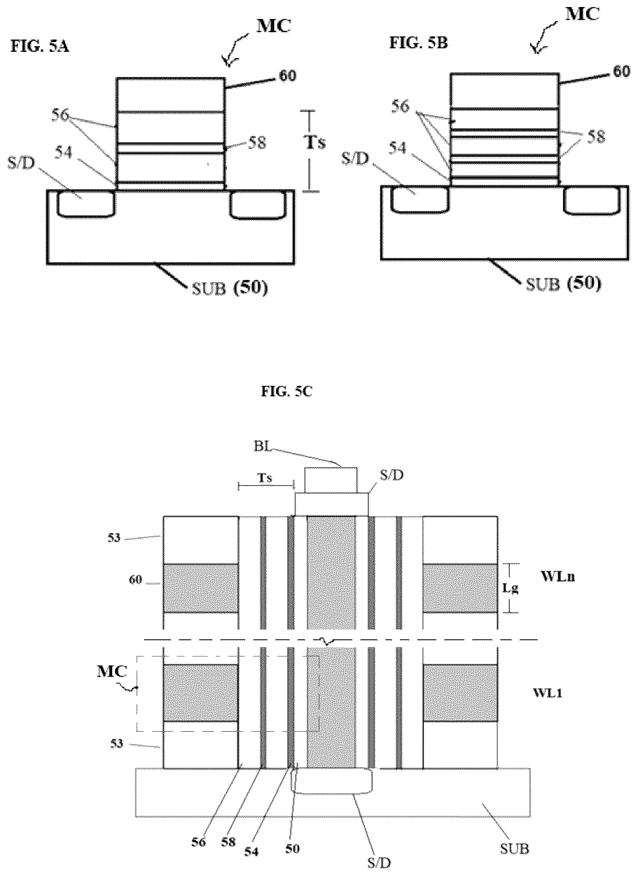

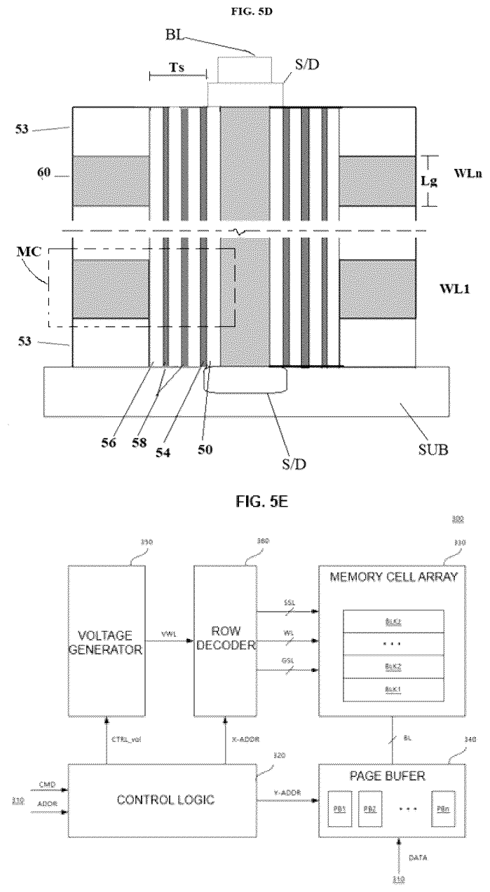

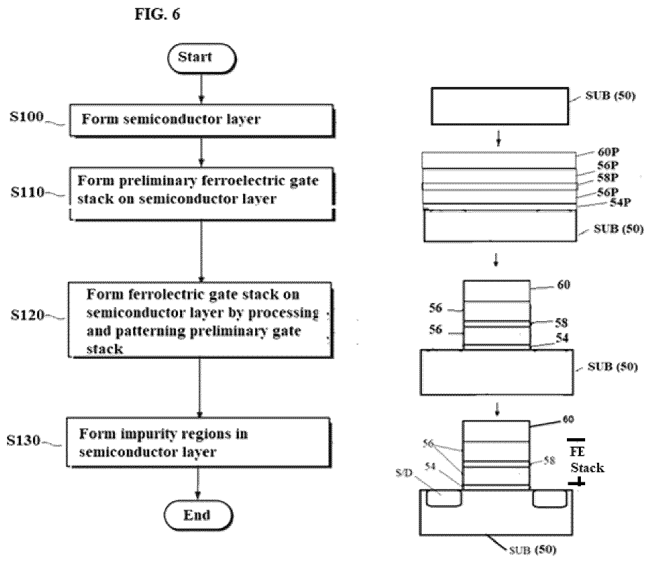

FIGS. 5A to 5D are cross-sectional views of memory devices according to some example embodiments.

Referring to FIG. 5A, in an example embodiment, a memory device may include the ferroelectric gate stack described with reference to FIG. 2A, where the semiconductor layer 50 may be at least part of substrate SUB. The substrate SUB may include impurity regions S/D spaced apart from each other near an upper surface of the substrate SUB. The interface layer 54, tunnel dielectric layer 58 sandwiched between a pair of ferroelectric layers 56, and conductor layer 60 may be stacked on a region of the substrate SUB between the impurity regions S/D. The region of the substrate SUB between the impurity regions S/D may provide a channel of the memory device. The impurity regions S/D respectively may provide a source connected to a first end of the channel and a drain connected to a second end of the channel.

The interface layer 54, tunnel dielectric layer 58 between the pair of ferroelectric layers 56, and conductor layer 60 stacked on the region of the substrate SUB between the impurity region S/D may define a memory cell MC.

Referring to FIG. 5B, in an example embodiment, a memory device may include the ferroelectric gate stack described with reference to FIG. 2B, where the semiconductor layer 50 may be at least part of substrate SUB. The substrate SUB may include impurity regions S/D spaced apart from each other near an upper surface of the substrate SUB. The interface layer 54, nanolaminate structure with three ferroelectric layers 56 and two tunnel dielectric layers 58 alternately stacked, and conductor layer 60 may be stacked on a region of the substrate SUB between the Impurity regions S/D.

Referring to FIG. 5C, in an example embodiment, the memory cell stack described in FIGS. 2C to 2E may be part of a memory device. The memory device may include a plurality of conductor layers 60 and insulating interlayers 53 alternately stacked on top of a substrate SUB. The conductor layers 60 may be word lines WL (WL1 to WLn). The word lines WL each may have a vertical thickness Lg. The conductor layers 60 and insulating interlayers 53 may define an opening O (see FIG. 2E) through the stack of conductor layers 60 and insulating interlayers 53. The semiconductor layer 50 may extend through the opening O in a direction perpendicular to an upper surface of the substrate SUB. The conductor layers 60 and the insulating interlayers 53 may surround the semiconductor layer 50.

An internal surface of the semiconductor layer 50 may surround an insulating filler layer 52. In some embodiments, the insulating filler layer 52 may be omitted and the semiconductor layer 50 may fill the area occupied by the insulating filler layer 52 in FIG. 5C. The semiconductor layer 50 and insulating filler layer 52 (if included) may be on top of an impurity region S/D formed in the substrate SUB. The impurity region S/D in the substrate SUB may be near an upper surface of the substrate SUB. The impurity region S/D in the substrate SUB may be a source. A semiconductor structure including an impurity region S/D may be formed on top of the semiconductor layer 50 and insulating filler 52 (if included). The impurity region S/D on top of the semiconductor layer 50 may be a drain. A bit line BL may be formed on top of the impurity region S/D over the semiconductor layer 50. The semiconductor layer 50 may provide a channel. The impurity regions S/D below and above the semiconductor layer 50 respectively may provide a source connected to a first end of the channel and a drain connected to a second end of the channel.

The interface layer 54 may surround an outer surface of the semiconductor layer 50 and may extend through the opening O. A ferroelectric (FE) stack surround an outer surface of the interface layer 54 and may extend in the same direction as the semiconductor layer 50 through the opening O. The FE stack may include a tunnel dielectric layer 58 sandwiched between two ferroelectric layers 56 and the tunnel dielectric layer 58 may extend in the same direction as the semiconductor layer 50 through the opening O. The ferroelectric layer 56 closest to the semiconductor layer 50 may be referred to as the first ferroelectric layer 56 and the ferroelectric layer 56 closest to the conductor layer 60 may be referred to as the second ferroelectric layer 56. Opposite surfaces of the tunnel dielectric layer 58 may directly contact the first ferroelectric layer 56 and the second ferroelectric layer 56, respectively. Opposite surfaces of the interface layer 54 may directly contact the first ferroelectric layer 56 and the semiconductor layer 50, respectively.

The memory device in FIG. 5C may include eight conductor layers 60, which may provide eight word lines (WL1 to WLn) stacked on top each other with insulating interlayers 53 therebetween, but the number of conductor layers 60 and insulating interlayers 53 alternately stacked is not particularly limited.

In FIG. 5C, a memory cell MC may be defined by portions of the interface layer 54, ferroelectric layer 56, tunnel dielectric layer 58, ferroelectric layer 56, and semiconductor layer 50 surrounded by a portion of the conductor layer 60 (WL) in a horizontal direction.

Referring to FIG. 5D, in an example embodiment, a memory device may be similar to memory device described in FIG. 5C except for the number of ferroelectric layers 56 and tunnel dielectric layers 58 between the conductor layers 60 and semiconductor layer 50. The memory device in FIG. 5E may include three ferroelectric layers 56 alternately arranged with two tunnel dielectric layers 56 between the conductor layer 60 and semiconductor layer 50. The memory cell stack described in FIGS. 2F to 2H may be part of the memory device in FIG. 5E.

In FIGS. 5A to 5D, the thickness Ts of the stack including the interface layer 54 and ferroelectric layers 56 alternately stacked with at least one tunnel dielectric layer 58 may less than or equal to 20 nm, but is not limited thereto.

FIG. 5E is a block diagram of a memory system according to an example embodiment.

Referring to FIG. 5E, the memory system 300 may include a control logic circuitry 320, a memory cell array 330, a page buffer 340, a voltage generator 350, and a row decoder 360.

The control logic circuitry 320 may control all various operations of the memory system 300. The control logic circuitry 320 may output various control signals in response to commands CMD and/or addresses ADDR from memory interface circuitry 310. For example, the control logic circuitry 320 may output a voltage control signal CTRL_vol, a row address X-ADDR, and a column address Y-ADDR. The memory interface circuitry 310 may communicate with a memory controller (now shown).

The memory cell array 330 may include a plurality of memory blocks BLK1 to BLKz (here, z is a positive integer), each of which may include a plurality of memory cells. The memory cell array 330 may be connected to the page buffer 340 through bit lines BL and be connected to the row decoder 360 through word lines WL, string selection lines SSL, and ground selection lines GSL.

In an example embodiment, the memory cell array 330 may include a 3D memory cell array, which may include a plurality of NAND strings arranged in a row direction and a column direction. In an example embodiment, the memory cell array 330 may include a 2D memory cell array, which includes a plurality of NAND strings arranged in a row direction and a column direction. Each NAND string may include a plurality of the memory cells arranged in series between a pair of selection transistors (e.g., a string selection transistor and a ground selection transistor), and the memory cells may have structures corresponding to the memory cells MC describes in any one of FIG. 5A, 5B, 5C, or 5D.

The page buffer 340 may include a plurality of page buffers PB1 to PBn (here, n is an integer greater than or equal to 3), which may be respectively connected to the memory cells through a plurality of bit lines BL. The page buffer 340 may select at least one of the bit lines BL in response to the column address Y-ADDR. The page buffer 340 may operate as a write driver or a sense amplifier according to an operation mode. For example, during a program operation, the page buffer 340 may apply a bit line voltage corresponding to data to be programmed, to the selected bit line. During a read operation, the page buffer 340 may sense current or a voltage of the selected bit line BL and sense data stored in the memory cell.

The voltage generator 350 may generate various kinds of voltages for program, read, and erase operations based on the voltage control signal CTRL_vol. For example, the voltage generator 350 may generate a program voltage, a read voltage, a program verification voltage, and an erase voltage as a word line voltage VWL.

The row decoder 360 may select one of a plurality of word lines WL and select one of a plurality of string selection lines SSL in response to the row address X-ADDR. For example, the row decoder 360 may apply the program voltage and the program verification voltage to the selected word line WL during a program operation and apply the read voltage to the selected word line WL during a read operation.

The control logic circuitry 330 may connect to a memory cells including ferroelectric layers in the memory cell array 330. The control logic circuitry 330 may be configured to switch a polarization state in the ferroelectric layers of the memory cell by controlling a program voltage or an erase voltage applied to the memory cell using the conductor layer of the memory cell.

The control logic circuitry 330 may operate the memory cell with a memory window sufficient for 2-bit operation by controlling a write voltage applied through the conductor layer to the memory cell so a level of the write voltage is sufficient for 2-bit operation (e.g., greater than or equal to 3.0 V). In some embodiments, a magnitude of the level of the write voltage sufficient for 2-bit operation may be greater than or equal to 7.0 V and less than or equal to 15.0 V.

The control logic circuitry 330 may be configured to operate the memory cell with a memory window sufficient for 3-bit operation by controlling a write voltage applied through the conductor layer to the memory cell so a level of the write voltage is sufficient for 3-bit operation (e.g., greater than or equal to 6.5 V). In some embodiments, a magnitude of the level of the write voltage sufficient for 3-bit operation may be greater than or equal to 12.0 V and less than or equal to 15.0 V.

The control logic circuitry 330 may be configured to control a memory operation on a memory cell in the memory cell array 330 by applying a pulse voltage using the conductor layer to the memory cell and then applying a read voltage to the memory cell using the conductor layer. The pulse voltage may be a program pulse voltage or an erase pulse voltage. A sign of the program pulse voltage may be opposite a sign of the erase pulse voltage. A magnitude of the read voltage may be less than a magnitude of the program pulse voltage and a less than a magnitude of the erase pulse voltage.

FIG. 6 is a flow chart with cross-sectional diagrams for explaining to a method of manufacturing a ferroelectric gate stack and a memory device according to an example embodiment.

In operation S100, a semiconductor layer may be formed. The semiconductor layer 50 may be formed as at least part of a semiconductor substrate SUB. Alternatively, although not illustrated, the semiconductor layer 50 may be formed as a separate layer on top of the substrate SUB.

In operation S110, a preliminary ferroelectric gate stack may be formed on the semiconductor layer 50 by forming a preliminary interface layer 54P on the semiconductor layer 50, forming a plurality of preliminary ferroelectric layers 56P alternately stacked with a preliminary tunnel dielectric layer 58P on the preliminary interface layer 54P, and forming a preliminary conductor layer 60P on an uppermost preliminary ferroelectric layer 56P among the preliminary ferroelectric layers 56P.

The preliminary interface layer 54P, preliminary ferroelectric layers 56P, preliminary tunnel dielectric layer 58P, and preliminary conductor layer 60P may be formed with the same materials respectively as the interface layer 54, ferroelectric layers 56, tunnel dielectric layer 58, and conductor layer 60 described above.

The preliminary interface layer 54P, preliminary ferroelectric layers 56P, preliminary tunnel dielectric layer 58P, and preliminary conductor layer 60P may be formed extending parallel to each other and parallel to an upper surface of the semiconductor layer 50.

The preliminary interface layer 54P may be formed directly on the semiconductor layer 50. The plurality of preliminary ferroelectric layers 56P alternately stacked with a preliminary tunnel dielectric layer 58P may be formed directly on the preliminary interface layer 54P. The preliminary conductor layer 60 may be is formed directly on an uppermost one of the plurality of preliminary ferroelectric layers 56P.

In operation S120, a ferroelectric gate stack may be formed on the semiconductor layer 50 by processing and patterning the preliminary ferroelectric gate stack. Processing the preliminary ferroelectric gate stack may include performing an annealing process.

In operation S130, a memory device may be formed by forming impurity regions S/D in the semiconductor layer 50.

The method FIG. 6 may be modified by forming a preliminary ferroelectric gate stack including three preliminary ferroelectric layers 56P alternately stacked with two preliminary tunnel dielectric layers 58P to manufacture the ferroelectric gate stack in FIG. 2B and the memory device in FIG. 5B.

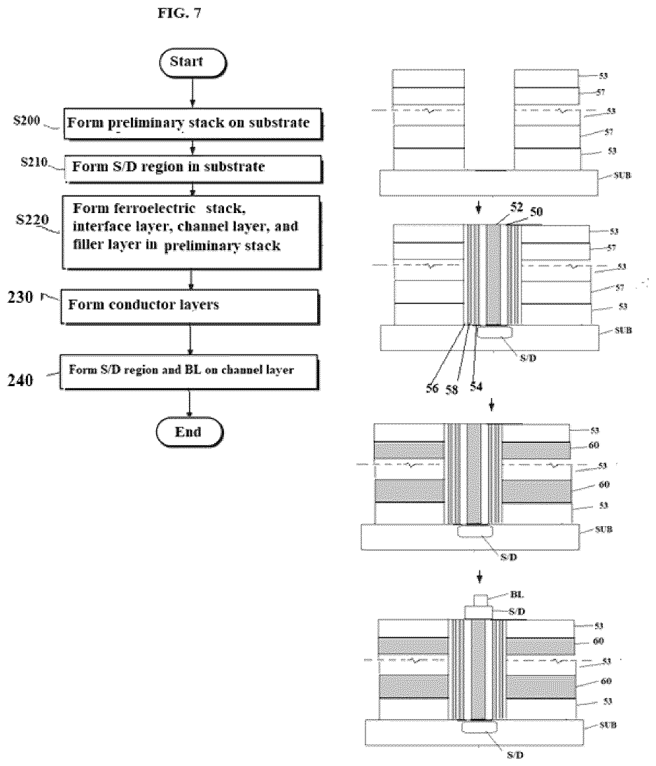

FIG. 7 is a flow chart with cross-sectional diagrams for explaining a method of manufacturing a ferroelectric gate stack and a memory device according to an example embodiment.

In operation S200, a preliminary stack may be formed on a substrate SUB by alternately stacking a plurality of insulating interlayers 53 and a plurality of sacrificial layers 57 on the substrate. The plurality of sacrificial layers 57 may include a material with etch selectivity compared to the plurality of insulating interlayers 53. For example, the sacrificial layers 57 may include silicon nitride and the insulating interlayers 53 may include silicon oxide, but example embodiments are not limited thereto. A patterning process may be formed to form an opening extending the through the stack of insulating interlayers 53 and sacrificial layers 57 to expose an upper surface of the substrate SUB.

In operation S210, an impurity region S/D may be formed in portion of the substrate SUB exposed by the opening in the preliminary stack.

In operation S220, a FE stack, interface layer 54, semiconductor layer 50, and filler layer 52 may be formed in the opening of the preliminary stack. The semiconductor layer 50 may surround the filler layer 52. The interface layer 54 may surround the semiconductor layer 50. The FE stack may surround the interface layer 54 and may include a tunnel dielectric layer 58 sandwiched between a pair of ferroelectric layers 56. The semiconductor layer 50 may be referred to as a channel layer. The semiconductor layer 50 may extend in a direction perpendicular to an upper surface of the substrate SUB.

In operation S230, conductor layers 60 may be formed by replacing the sacrificial layers 57 with a material of the conductor layers 60.

In operation S240, an impurity region S/D may be formed on top of the semiconductor layer 50 and a bit line BL may be formed on top of the impurity region S/D on the semiconductor layer 50.

The method FIG. 7 may be modified by forming a FE stack including three ferroelectric layers 56 alternately arranged with two tunnel dielectric layers 58 to manufacture the ferroelectric gate stack in FIG. 2F to 2H and the memory device in FIG. 5D. An outermost ferroelectric layer 56 in the FE stack may directly contact the conductor layers 60. An innermost ferroelectric layer 56 in the FE stack may directly contact the interface layer 54. Opposite surfaces of a tunnel dielectric layer 58 in the FE stack may be in contact with a pair of ferroelectric layers 56 adjacent to each other.

In solutions according to example embodiments discussed above, the inventors of the present application have experimentally demonstrated, for the first time, a novel dipole engineering scheme for FE gate stack design by the insertion of an tunnel dielectric layer (TDL) in the middle of the ferroelectric (FE) stack to achieve high MW (≥3.0 V, ≥6.5 V) in FE stack within the NAND thickness limit (≤20 nm).

According to example embodiments, the engineered FE stack with a tunnel dielectric layer (TDL) exhibits a more than 2×MW enhancement as compared to that without the TDL with the same total thickness and write voltage ≤15 V. By doing so, example embodiments of inventive concepts present an innovative scheme for ferroelectric gate stack design, where trap dynamics are leveraged to enhance the MW. This approach differs from the conventional role (see FIG. 1) of trapped charges working against the ferroelectric effect, marking the first time such a scheme has been identified.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the example embodiments have been illustrated and described above, it will be configured as apparent to those skilled in the art that modifications and variations could be made without departing from the scope of the present disclosure as defined by the appended claims.

1. A ferroelectric gate stack, comprising:
a semiconductor layer;
a conductor layer facing the semiconductor layer;
a plurality of ferroelectric layers spaced apart from each other between the semiconductor layer and the conductor layer, the plurality of ferroelectric layers including a first ferroelectric layer and a second ferroelectric layer;
a tunnel dielectric layer between the first ferroelectric layer and the second ferroelectric layer; and
an interface layer between the semiconductor layer and the first ferroelectric layer.

2. The ferroelectric gate stack of claim 1, wherein
the interface layer includes an oxide of a material in the semiconductor layer, and
the plurality of ferroelectric layers are a different material than the interface layer.

3. The ferroelectric gate stack of claim 1, wherein
the plurality of ferroelectric layers include hafnium zirconium oxide, and
the tunnel dielectric layer includes aluminum oxide.

4. The ferroelectric gate stack of claim 1, wherein
the semiconductor layer and the conductor layer are separated from each other by a distance of less than or equal to 20 nm, and
the plurality of ferroelectric layers, the tunnel dielectric layer, and the interface layer define a stacked structure having a thickness of less than or equal to 20 nm.

5. The ferroelectric gate stack of claim 1, wherein
the plurality of ferroelectric layers include a third ferroelectric layer on the second ferroelectric layer,
the tunnel dielectric layer is a first tunnel dielectric layer among a plurality of tunnel dielectric layers between the semiconductor layer and the conductor layer, and
the plurality of tunnel dielectric layers include a second tunnel dielectric layer between the second ferroelectric layer and the third ferroelectric layer.

6. The ferroelectric gate stack of claim 1, wherein
the conductor layer does not surround the semiconductor layer,
opposite surfaces of the tunnel dielectric layer directly contact the first ferroelectric layer and the second ferroelectric layer, respectively, and
opposite surfaces of the interface layer directly contact the first ferroelectric layer and the semiconductor layer, respectively.

7. The ferroelectric gate stack of claim 1, wherein
the conductor layer surrounds the semiconductor layer,
opposite surfaces of the tunnel dielectric layer directly contact the first ferroelectric layer and the second ferroelectric layer, respectively, and
opposite surfaces of the interface layer directly contact the first ferroelectric layer and the semiconductor layer, respectively.

8. The ferroelectric gate stack of claim 1, wherein
the plurality of ferroelectric layers are thicker than the tunnel dielectric layer.

9. The ferroelectric gate stack of claim 1, wherein
the conductor layer directly contacts one of the plurality of ferroelectric layers that is farthest away from the semiconductor layer among the plurality of ferroelectric layers.

10. The ferroelectric gate stack of claim 1, wherein
a thickness of the tunnel dielectric layer is 0.5 nm to 3.0 nm, and
the plurality of ferroelectric layers each have a thickness of 6 nm to 10 nm.

11. A memory device, comprising:
a channel;
a source connected to a first end of the channel;
a drain connected to a second end of the channel;
a conductor layer facing the channel;
a plurality of ferroelectric layers spaced apart from each other between the channel and the conductor layer, the plurality of ferroelectric layers including a first ferroelectric layer and a second ferroelectric layer;
a tunnel dielectric layer between the first ferroelectric layer and the second ferroelectric layer; and
an interface layer between the channel and the first ferroelectric layer.

12. The memory device of claim 11, further comprising:
processing circuitry connected to a memory cell including the plurality of ferroelectric layers, wherein
the processing circuitry is configured to switch a polarization state in a corresponding one of the plurality of ferroelectric layers by controlling a program voltage or an erase voltage applied to the memory cell using the conductor layer.

13. The memory device of claim 12, wherein
the processing circuitry is configured to operate the memory cell with a memory window sufficient for 2-bit operation by controlling a write voltage applied through the conductor layer to the memory cell so a level of the write voltage is sufficient for 2-bit operation,
the memory window sufficient for 2-bit operation is greater than or equal to 3.0 V, and
a magnitude of the level of the write voltage sufficient for 2-bit operation is greater than or equal to 7.0 V and less than or equal to 15.0 V.

14. The memory device of claim 12, wherein
the processing circuitry is configured to operate the memory cell with a memory window sufficient for 3-bit operation by controlling a write voltage applied through the conductor layer to the memory cell so a level of the write voltage is sufficient for 3-bit operation,
the memory window sufficient for 3-bit operation is greater than or equal to 6.5 V, and
a magnitude of the level of the write voltage sufficient for 3-bit operation is greater than or equal to 12.0 V and less than or equal to 15.0 V.

15. The memory device of claim 11, further comprising:
processing circuitry connected to a memory cell including the plurality of ferroelectric layers, wherein
the processing circuitry is configured to control a memory operation on the memory cell by applying a pulse voltage using the conductor layer to the memory cell and then applying a read voltage to the memory cell using the conductor layer,
the pulse voltage is a program pulse voltage or an erase pulse voltage,
a sign of the program pulse voltage is opposite a sign of the erase pulse voltage, and
a magnitude of the read voltage is less than a magnitude of the program pulse voltage and a less than a magnitude of the erase pulse voltage.

16. The memory device of claim 11, wherein
the conductor layer does not surround the channel, or
the conductor layer surrounds the channel and the channel extends through an opening defined in the conductor layer.

17. The memory device of claim 11, wherein
the interface layer includes an oxide of a material in channel, and
the plurality of ferroelectric layers are a different material than a material of the tunnel dielectric layer,
opposite surfaces of the interface layer directly contact the channel and the first ferroelectric layer, respectively,
the plurality of ferroelectric layers each are thicker than the tunnel dielectric layer, and
a distance between the channel and the conductor layer is 20 nm or less and corresponds to a thickness of a stacked structure consisting of the plurality of ferroelectric layers, the tunnel dielectric layer, and the interface layer.

18. A ferroelectric gate stack, comprising:
a semiconductor layer;
a conductor layer facing the semiconductor layer;
a ferroelectric (FE) stack between the semiconductor layer and the conductor layer, the FE stack including a plurality of ferroelectric material regions separated from each other by one or more tunnel dielectric regions in contact with the plurality of ferroelectric material regions; and
an interface layer between the semiconductor layer and the FE stack, wherein
the plurality of ferroelectric material regions include a ferroelectric material, and
the one or more tunnel dielectric regions include a dielectric material configured to increase a memory window of the ferroelectric gate stack,
the ferroelectric material is different than the dielectric material and different than a material of the interface layer, and
opposite surfaces of the interface layer are in contact with the semiconductor layer and the FE stack.

19. The ferroelectric gate stack of claim 18, wherein
a thickness of the FE stack is less than or equal to 20 nm in a direction corresponding to a minimum distance between the semiconductor layer from the conductor layer.

20. The ferroelectric gate stack of claim 18, wherein
the plurality of ferroelectric regions include hafnium zirconium oxide,
the one or more tunnel dielectric regions include aluminum oxide,
the interface layer includes an oxide of a material in the semiconductor layer.

21.-25. (canceled)
